(19) United States
(12) Patent Application Publication
(10) Pub. No.: US 2007/0163873 A1
(43) Pub. Date: Jul. 19, 2007

(54) Target material and its use in a sputter process

(76) Inventors: Gerd Kleideiter, Ahaus (DE); Anton Zmelty, Hosbach (DE); Michael Geisler, Wachtersbach (DE)

Correspondence Address: FULBRIGHT & JAWORSKI, LLP, 666 FIFTH AVE, NEW YORK, NY, 10103-3198, US

(21) Appl. No.: 11/587,300

(22) PCT Filed: Jun. 2, 2004
(86) PCT No.: PCT/EP04/05923

§ 371 Date: Mar. 2, 2007

(51) Int. Cl. C23C 14/00

(52) U.S. Cl. 204/192.28; 204/298.13

(57) ABSTRACT

The invention relates to a target material for the production of a protective layer for a solar control and absorption layer by means of sputtering. This target material is comprised of silicon doped with titanium. The protective layer, which can be produced with the target material, is heatable without significant changes of its properties. It is therefore also suitable for coating lass, which is heated and subsequently bent.

The invention relates to a target material according to the preamble of patent claim 1 as well as to the use of same.

It relates to the field of glass coating, in particular the coating of glass with a heat-treatable sun protection layer system.

Coated glass, which is to be bent, is required for many applications. Such an application is, for example, a curved window pane on the corner of a building, which serves as a display window. The process of uniformly coating bent glass is technically very difficult. For that reason attempts have been made to coat the glass first and then to deform it subsequently. However, here the problem is encountered that the coating peels off or forms bubbles. The problem of peeling or bubble formation also occurs with planar architectural glass which only needs to be warmed. Architectural glass is heated for a few minutes to temperatures of approximately 700° C. and subsequently cooled very rapidly. In the event the glass is destroyed, the glass, unlike untempered glass, breaks into many small glass splinters due to these heating and cooling processes. This property is often demanded for technical safety reasons.

A method for the production of a thermally treated coated glass is already known, in which, first, a solar control layer or an electrically conducting layer is formed on a glass substrate and thereon a protective layer is deposited (EP 0 546 302 B1). The solar control layer here is comprised of a metal, for example corrosion-resistant steel, titanium, chromium, zirconium, tantalum or hafnium or of a nitride, boride or carbide of these metals. The protective layer, on the other hand, comprises for example boron nitride, silicon nitride, silicon nitride or carbonitride.

In addition, coated glass is known, which can be subjected to heat treatment and in which a heat protection film and a further protective film are layered one above the other (EP 0 501 632 B1). The further protective film is transparent for the wavelength of visible light and is fabricated of a silicon oxinitride, represented by the formula SiOₓN_{y}, where x is in the range of 0.65 to 1.25 and y in the range of 0.05 to 0.67.

In another heat-treatable glass pane the coating contains a metal nitride layer, enclosed between two dielectric layers (WO 02/090281 A2). One of the dielectric layers is herein at least partially nitrated and disposed such that the metal nitride layer is between these dielectric layers and the glass substrate.

A sputter target is also known, which serves for the deposition of nitridic or oxidic silicon layers (DE 198 10 246 A1). This sputter target comprises a solidified formed silicon body with a doping substance added in the melt. The doping substance is comprised of 1 to 15 percent by weight of aluminum.

The invention addresses the problem of providing a temperable coating for a substrate by means of sputtering in which a very high sputter rate is attained.

This problem is solved according to the characteristics of patent claim 1.

The invention consequently relates to a target material for the production of a protective layer for a solar control and absorption layer by means of sputtering. This target material is comprised of silicon doped with titanium. The protective layer, which can be produced with the target material, is heatable without its properties changing significantly. It is therefore also suitable for coating glass which is heated and subsequently bent.

One advantage attained with the invention comprises that the layer system shields against sun light and heat radiation with a transmission between 5 and 50% and in which the transmission is settable. In addition, the layer system can have different reflection colors, and these different colors can also readily be set.

The layer system is furthermore mechanically highly stable and has high scratch resistance. Therewith individual glazings having a long service life are possible. The fact that the layer is temperable, permits the efficient production sequence with coating, cutting, tempering. A further advantage of the invention comprises that during the tempering optical parameters, such as color, transmission and reflection, change not at all or only slightly. The scattered light component, i.e. the so-called haze values, hardly increase during the tempering.

An advantage of the target materials according to the invention for Si:Ti as well as also for AlSi:Ti is the sputter rate which is approximately 20% higher compared to pure silicon. This higher sputter rate can be ascribed to the titanium doping. The titanium furthermore leads to better adhesion of ceramic layers, such as titanium-containing silicon nitride, on metal layers. The improved adhesion of titanium-containing ceramic layers on, for example, chromium, is thought to be due to Ti—Cr bridges.

An embodiment example of the invention is shown in the drawing and will be explained in further detail in the following. In the drawing depict:

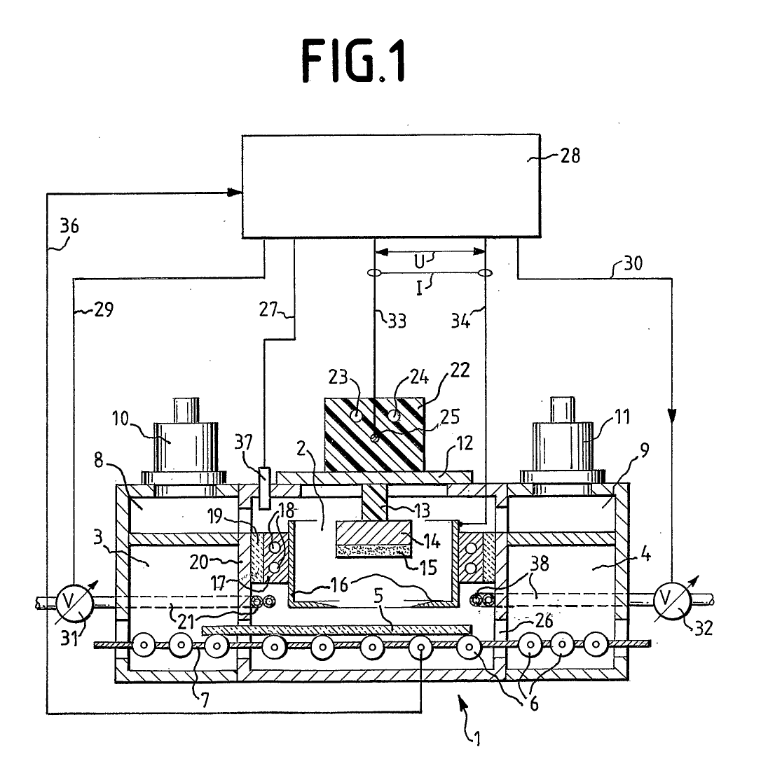

FIG. 1 a cross section through a sputter chamber,

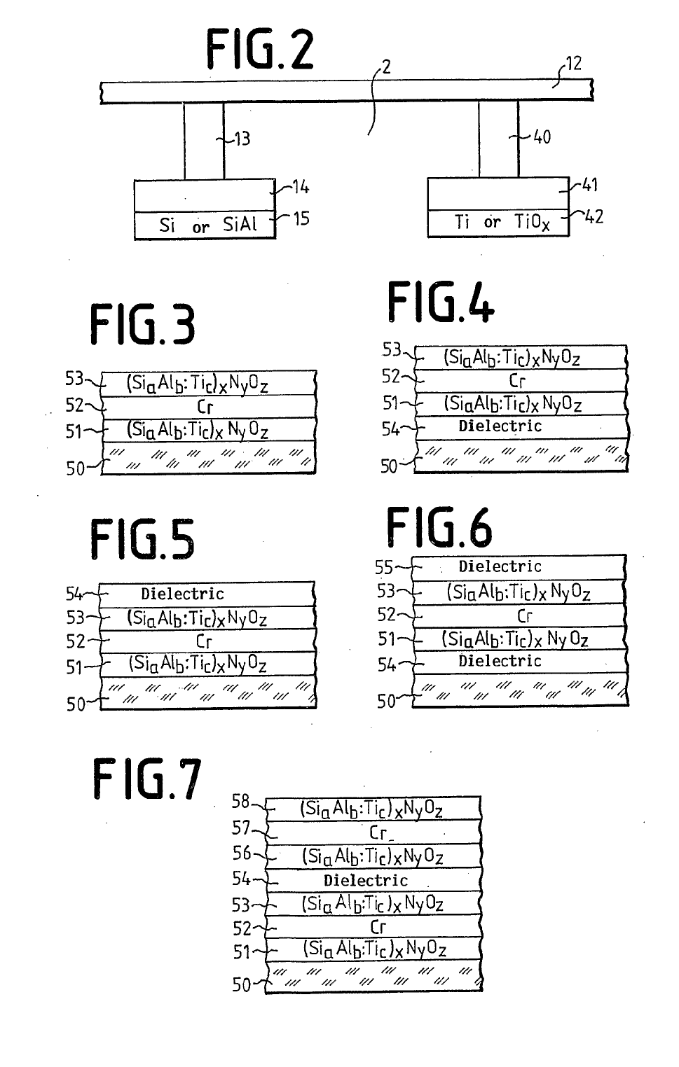

FIG. 2 a detail of a sputter chamber,

FIG. 3 a first multiple-layer coating of a substrate,

FIG. 4 a second multiple-layer coating of a substrate,

FIG. 5 a third multiple-layer coating of a substrate,

FIG. 6 a fourth multiple-layer coating of a substrate,

FIG. 7 a fifth multiple-layer coating of a substrate.

FIG. 1 shows a cross section through a sputter chamber 1, in which the coating of a substrate takes place. This sputter chamber 1 comprises the coating chamber 2 proper and two buffer chambers 3, 4. Adjoining this sputter chamber 1 can be on the right and/or on the left further sputter chambers, which are not shown. A substrate 5 is transported from the left to the right via transport rollers 6 supported in a support 7. Above the buffer chamber 3, 4 is located in each instance a pumping chamber 8, 9, and above each pumping chamber 8, 9 a pump 10, 11 is disposed.

Between the pumps 10, 11 is disposed an installation cover 12, on whose underside a cathode mount 13 is fastened, which supports a cathode 14 with a target 15. This target 15 is comprised of a composition of silicon, aluminum and titanium or only silicon and titanium. An anode 16 beneath the target 15 is fastened on a mount 17, which includes a cooling system 18 and is connected across an insulation 19 with a wall 20 of the coating chamber 2. Next to the anode 16 are provided supply lines 21, 38 for sputter gases. In a cathode covering hood 22 are provided cathode cooling water conduits 23, 24, which serve for the forward and return transport of cooling water. By 25 is denoted the cathode connection. A gap interlock 26 connects the coating chamber 2 with the buffer chamber 4.

37 denotes a pressure sensor, which via a line 27 is connected with a control 28 and measures the pressure in the coating chamber 2. The gas pressure in the coating chamber 2 is controlled according to the measured pressure via control lines 29, 30 and valves 31, 32 and the cathode-anode voltage via lines 33, 34.

The two gas lines 21, 38 extend on both sides along the cathode 14. The two outer lines 21 and the two inner lines 38 are in each instance connected with one another.

The voltage and the current of the plasma discharge are measured via lines 33, 34, and specifically time-dependent, in order to determine the instantaneous power.

It is important for the present invention that target 15 is a ceramic Si or SiAl target, which is doped with titanium. If this target is sputtered while nitrogen and oxygen are supplied, an (SiAl:Ti)NO layer is formed on the substrate 5 if, for example, the fraction of Ti is 2 percent by weight, Al 10 percent by weight and Si 88 percent by weight. However, a mixture of 0.5 to 50 percent by weight of titanium would also be possible. The colon between SiAl and Ti indicates that the material in front of the colon is doped with titanium.

The (SiAl:Ti)NO layer is preferably produced by means of a mixed target. It is, however, also possible to apply this layer by simultaneously sputtering two targets. The first target in this case could be a metallic Ti target or a ceramic TiOₓ target, while the second target in this case would be an Si or an SiAl target. It is also conceivable to mix the aluminum with the titanium. All variants of sputtering could in principle be employed, i.e. planar as well as also rotating cathodes, DC and AC sputtering.

Of importance for the layer is that titanium and silicon form a compound with oxygen or with nitrogen. Thus a reactive sputter process must take place in an oxygen and nitrogen-containing atmosphere. These gases are introduced through lines 21, 38 into the sputter chamber. In this case layers result which, apart from Al compounds, contain additionally also the reaction products TiO₂, TiN, SiO₂ and Si₃N₄ in varying amounts. Titanium can also form a compound with hydrogen, since hydrogen, due to the dissociation of water, is present in the background atmosphere. Titanium hydride improves the adhesion capacity of the sputtered layers. Consequently, it is of advantage if at least small quantities of water or hydrogen-containing gas are supplied to the process gas. Known hydrogen-containing gases are for example the so-called forming gases, nitrogen-hydrogen mixtures or mixtures of argon and hydrogen.

It is unexpected that optically transparent layers are generated although pure TiN in thicker layers has a golden color and is not transparent. The aluminum fraction is not required for the layer properties; it serves to improve the workability of the silicon target, which, starting at an aluminum content of approximately 5%, markedly loses the brittleness of pure aluminum. In addition, the sputter properties are also improved by adding aluminum.

If, when sputtering with two targets, one target of TiOₓ is employed, even without the addition of oxygen an (SiₐAl_{b}:Ti_{c})ₓ N_{y}O_{z} layer can be formed, which has a greater component of oxygen. The indices a, b, c, x, y, z represent integers.

In adaptation to the particular adjacent layers, the protective layer (SiₐAl_{b}:Ti_{c})ₓ N_{y}O_{z} can also vary from (SiₐAl_{b}:Ti_{c}) N to (SiₐAl_{b}:Ti_{c}) O.

In FIG. 2 a detail of the coating chamber 2 is depicted, where two targets 15, 42 are employed. Target 15 here comprises Si or SiAl, while the other target 42 is comprised of metallic Ti or of TiOₓ. If the target is comprised of SiAl, the silicon is doped with 1% to 15% of aluminum since hereby the mechanical properties of the otherwise brittle silicon are improved. Both targets 15, 42 are connected via cathodes 14, 41 and cathode mounts 13, 40 with the installation cover 12.

Both targets 15, 42 can be sputtered simultaneously or sequentially. The target with which the solar control layer or the absorber layer is produced, is not shown in FIG. 1 and 2.

FIG. 3 shows a first layer sequence on a glass substrate 50. The layer sequence comprises a layer 51 of (SiₐAl_{b}:Ti_{c})ₓ N_{y}O_{z}, a solar control layer 52, preferably of metal, here chromium, and a further layer 53 of (SiₐAl_{b}:Ti_{c})ₓ N_{y}O_{z}.

In FIG. 4 is shown a layer sequence which differs from that of FIG. 3 thereby that an additional dielectric 54 is provided directly on the glass substrate 50.

A further layer sequence is shown in FIG. 5. It differs from the layer sequence according to FIG. 4 thereby that the additional dielectric 54 is superjacent on the upper layer 53.

FIG. 6 shows a further layer sequence, which differs from the layer sequence according to FIG. 4 thereby that additionally a second dielectric 55 is provided, which closes off the upper layer 53 against the outside.

In FIG. 7 is depicted a further layer sequence, which corresponds to the layer sequence according to FIG. 5, but which, additionally, comprises a layer sequence 56, 57, 58 corresponding to the layer sequence 51, 52, 53 according to FIG. 3.

The sputter rates, which are obtained using the same generator and a target area of 1500 cm², are the following:

| | |
|---|---|
| Polycrystalline Si: | electric power 18.1 kW, rate: 30 nm * m/min |
| Amorphous SiAl: | electric power 18.0 kW, rate: 34 nm * m/min |
| Amorphous SiAl:Ti: | electric power 18.5 kW, rate: 42 nm * m/min |

1-16. (canceled)

17. A target material comprising silicon and between 0.5 and 50 percent by weight titanium.

18. The target material of claim 17, wherein the target material additionally comprises aluminum.

19. The target material of claim 17, wherein the fraction of titanium is 2 percent by weight, the fraction of aluminum 10 percent by weight and the fraction of silicon 88 percent by weight.

20. The target material of claim 17, wherein it is realized as an alloy in a single target.

21. The target material as claimed in claim 18, wherein the target material is provided in the form of two targets, wherein one target is a metallic Ti target and the other target is an SiAl target.

22. The target material as claimed in claim 18, wherein two targets are provided, wherein one target is a TiOₓ target and the other target an SiAl target.

23. The target material as claimed in claim 20, wherein the target is a cylindrical target rotating about a longitudinal axis and relative to the magnets of a magnetron.

24. A method comprising implementing the target material of claim 17 in a sputter process performed in a chamber, and introducing nitrogen and oxygen into the chamber, such that a protective layer of (SiₐAl_{b}:Ti_{c})ₓ N_{y}O_{z} is formed, where a, b, c, x, y, z are integers greater than zero.

25. A method comprising implementing the target material of claim 17 in a sputter process performed in a chamber and introducing nitrogen and oxygen into the chamber such that a protective layer of (Siₐ:Ti_{b})ₓ N_{y}O_{z} is formed, where a, b, x, y and z are integers greater than zero.

26. The method of claim 24, wherein the oxygen content or the nitrogen content of the (SiₐAl_{b}:Ti_{c})ₓ N_{y}O_{z} layer decreases in the direction to the absorption layer.

27. The method of claim 24, wherein at least one of the oxygen content or the nitrogen content of the (Siₐ:Ti_{b})ₓ N_{y}O_{z} layer decreases in the direction of the absorption layer.

28. The method of claim 24, for embedding in a solar control and absorption layer.

29. The method of claim 28, wherein the embedded solar control and absorption layer is a coating on glass.

30. The method of claim 29, wherein a dielectric is provided between the glass and the embedded solar control and absorption layer.

31. The method of claim 29, wherein a dielectric is provided on the outer protective layer.

32. The method of claim 29, wherein it is embedded between two dielectrics, wherein one of the dielectrics is in contact on glass.

33. The method of claim 29, wherein two embedded control and absorption layers are provided and is disposed therebetween.
